(19) United States
(12) Patent Application Publication
(10) Pub. No.: US 2026/0032816 A1
(43) Pub. Date: Jan. 29, 2026

(54) NON-SHARED ANTIPADS OF POWER VIAS IN A PRINTED CIRCUIT BOARD

(71) Applicant: DELL PRODUCTS L.P., Round Rock, TX (US)

(72) Inventors: Arun Chada, Pflugerville, TX (US); Soumya Singh, Bangalore (IN); Seema P K, Bangalore (IN); Bhyrav Mutnury, Round Rock, TX (US); Junho Joo, Rolla, MO (US)

(21) Appl. No.: 18/784,496

(22) Filed: Jul. 25, 2024

(51) Int. Cl. H05K 1/11; H05K 1/02; H05K 1/18; H05K 3/40

(52) U.S. Cl. CPC H05K 1/112; H05K 1/0228; H05K 1/185; H05K 3/4007; H05K 3/4038; H05K 2201/09609

(57) ABSTRACT

A printed circuit board includes a substrate, a trace, first and second ground layers, first and second power vias, and first, second, third and fourth antipads. The trace is routed along a signal layer and the power vias are adjacent to the trace within the substrate. The first and second antipads are around the first power via. The first antipad is located within the first ground layer and the second antipad is located within the second ground layer. The third and fourth antipads are around the second power via. The third antipad is located within the first ground layer and the fourth antipad is located the second ground layer. The first and third antipads are non-shared antipads between the first and second power vias, and the second and fourth antipads are non-shared antipads between the first and second power vias.

### FIELD OF THE DISCLOSURE

The present disclosure generally relates to information handling systems, and more particularly relates to a design for non-shared antipads of power vias in a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A printed circuit board includes a substrate, a trace, first and second ground layers, first and second power vias, and first, second, third and fourth antipads. The trace may be routed along a signal layer within the substrate, and the power vias may be adjacent to the trace within the substrate. The first and second antipads may be around the first power via. The first antipad may be located within the first ground layer of the substrate and the second antipad may be located within the second ground layer of the substrate. The third and fourth antipads may be around the second power via. The third antipad may be located within the first ground layer and the fourth antipad may be located the second ground layer of the substrate. The first and third antipads are non-shared antipads between the first and second power vias, and the second and fourth antipads are non-shared antipads between the first and second power vias.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram illustrating a cross-section of a portion of a printed circuit board according to at least one embodiment of the present disclosure;

FIG. 2 is a diagram illustrating a top view of a portion of a printed circuit board having two columns of power vias according to at least one embodiment of the present disclosure;

FIG. 3 is a diagram illustrating a top view of a portion of a printed circuit board having staggered power vias according to at least one embodiment of the present disclosure;

FIG. 4 is a flow diagram of a method for fabricating a printed circuit board with power vias having non-shared antipads; and

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

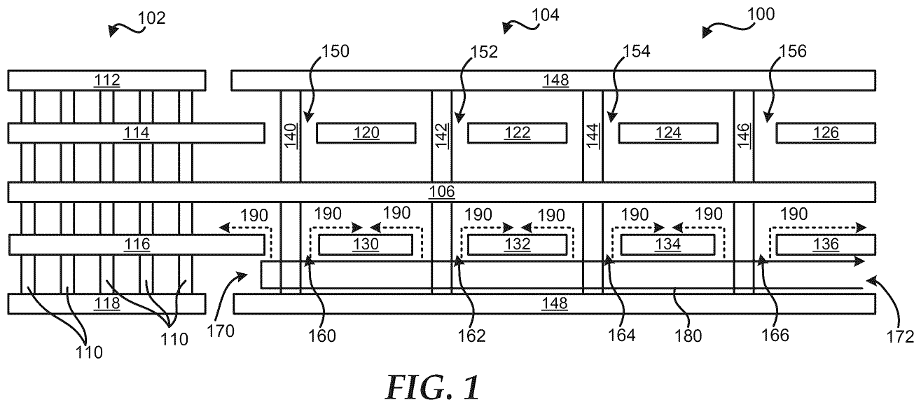

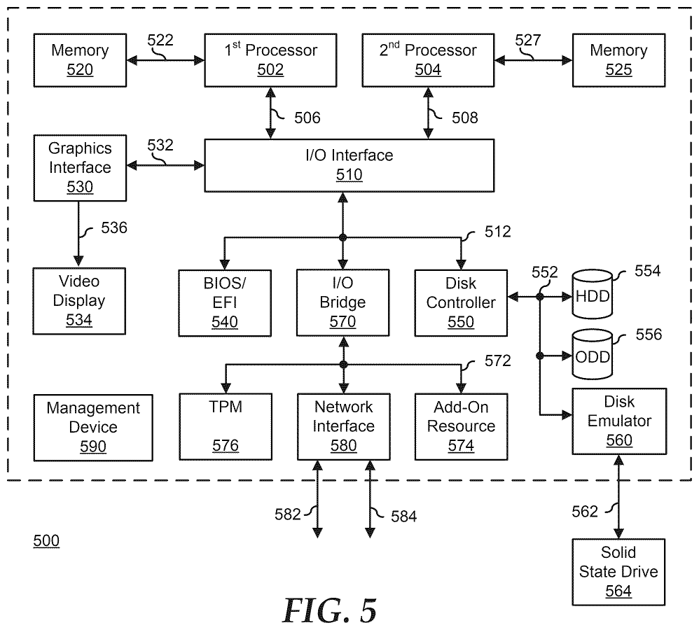

FIG. 1 illustrates a portion of a printed circuit board 100 to be included in an information handling system, such as information handling system 500 of FIG. 5, according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Printed circuit board 100 includes a ground region 102, a voltage regulator module (VRM) region 104, and a signal trace or stripline 106. Ground region 102 includes multiple ground vias 110 and different ground layers 112, 114, 116, and 118. Ground layer 114 includes different portions 120, 122, 124, and 126 that are located within VRM region 104. Similarly, ground layer 116 includes different portions 130, 132, 134, and 136 that are located within VRM region 104. VRM region 104 includes multiple power vias 140, 142, 144, and 146 to connect power layers 148 on opposite sides of printed circuit board 100. Signal trace or stripline 106 is adjacent to, but does not intersection with, ground vias 110 and power vias 140, 142, 144, and 146. Printed circuit board 100 may include additional components without varying from the scope of this disclosure.

As illustrated, power via 140 may have an antipad 150 around the power via where the power via intersects ground layer 114 and an antipad 160 around the power via where the power via intersects ground layer 116. Similarly, power via 142 may have an antipad 152 around the power via where the power via intersects ground layer 114 and an antipad 162 around the power via where the power via intersects ground layer 116. Power via 144 may have an antipad 154 around the power via where the power via intersects ground layer 114 and an antipad 164 around the power via where the power via intersects ground layer 116. Power via 146 may have an antipad 156 around the power via where the power via intersects ground layer 114 and an antipad 166 around the power via where the power via intersects ground layer 116.

VRM region 104 further includes a VRM circuit port 170 and an input voltage port 172. In an example, a conduction current loop 180 may circulate in the direction illustrated in FIG. 1, such as along power layer 148, into and along ground layer 116, and back into the power layer. In certain examples, VRM region 104 may be a multiphase buck converter to provide power to a central processing unit (CPU) and other devices of an information handling system, such as processor 502 or 504 of information handling system 500 in FIG. 5. However, in current printed circuit boards, VRMs may generate high-frequency noise that may disrupt or reduce the signal integrity of high speed signals transmitted in traces or striplines adjacent to power vias. This noise from the power vias may be caused by a significant amount of noise coupling between the power vias and the adjacent signal trace or stripline. In some situations, the noise margins have become stringent, such as a little as a few millivolts and a few picoseconds.

Noise from the power vias may be coupled to the trace or stripline in any suitable manner including, but not limited to, VRM power via transition radiation and leaked return current through the antipad of the power via. In certain cases, the leakage current from the power via antipad may be the major contributor of power noise coupling to the trace. Printed circuit board 100 may be improved over current printed circuit board by different designs for non-shared antipads of power vias 140, 142, 144, and 146 to reduce noise coupling from leakage current.

In certain examples, antipads 150 and 160 prevent power via 140 from being in physical contact with respective ground layers 114 and 116. Similarly, antipads 152 and 162 prevent power via 142 from being in physical contact with respective ground layers 114 and 116. Antipads 154 and 164 prevent power via 144 from being in physical contact with respective ground layers 114 and 116, and antipads 156 and 166 prevent power via 146 from being in physical contact with respective ground layers 114 and 116. In an example, all antipads 150, 152, 154, 156, 160, 162, 164, and 166 are non-shared antipads. As used herein, non-shared antipads refers to antipads that do not overlap or connect, such that a continuous antipad is not formed and shared by more than one of power vias 140, 142, 144, and 146.

Non-shared antipads 150, 152, 154, 156, 160, 162, 164, and 166 may create different portions of ground layers 114 and 116 in between adjacent antipads and the corresponding power vias. For example, non-shared antipads 150 and 152 of corresponding power vias 140 and 142 create portion 120 of ground layer 114, and non-shared antipads 152 and 154 of corresponding power vias 142 and 144 create portion 122 of ground layer 114. Similarly, non-shared antipads 154 and 156 of corresponding power vias 144 and 146 create portion 124 of ground layer 114, and non-shared antipads 156 of power via 146 creates portion 126 of ground layer 114.

Non-shared antipads 160, 162, 164, 166, 170, 162, 164, and 166 may create different portions of ground layers 114 and 116 in between adjacent antipads and the corresponding power vias. For example, non-shared antipads 150 and 152 of corresponding power vias 140 and 142 create portion 120 of ground layer 114, and non-shared antipads 152 and 154 of corresponding power vias 142 and 144 create portion 122 of ground layer 114. Similarly, non-shared antipads 154 and 156 of corresponding power vias 144 and 146 create portion 124 of ground layer 114, and non-shared antipad 156 of power via 146 creates portion 126 of ground layer 114.

In an example, non-shared antipads 160 and 162 of corresponding power vias 140 and 142 create portion 130 of ground layer 116, and non-shared antipads 162 and 164 of corresponding power vias 142 and 144 create portion 132 of ground layer 116. Similarly, non-shared antipads 164 and 166 of corresponding power vias 144 and 146 create portion 134 of ground layer 116, and non-shared antipad 166 of power via 146 creates portion 136 of ground layer 114. In certain examples, portions 120, 122, 124, and 126 of ground layer 114 and portions 130, 132, 134, and 136 may reduce or lower the leaked current coupling between adjacent antipads, which in turn may reduce noise coupling from the leakage current to a signal propagated along trace or stripline 106. Portions 120, 122, 124, 126, 130, 132, 134, and 136 may be any suitable length to create a particular distance or spacing between adjacent antipads. For example, portions 120, 122, 124, 126, 130, 132, 134, and 136 may be 5 mils, 6 mils, 7 mils, or the like. One of ordinary skill in the art would recognize that mil is a unit of measurement utilized in routing on printed circuit boards, and one mil equals one-thousandth of an inch or two hundred fifty-four ten-thousandths of a millimeter. While portions 120, 122, 124, and 126 are illustrated as only being located in between corresponding power vias 140, 142, 144, and 146, ground layer 114 may include other portions that extend in all directions from antipads 150, 152, 154, and 156.

In certain examples, as the conduction current circulates along loop 180 among input voltage port 172, signal layer 148, VRM circuit port 170, and ground layer 116, a leakage current 190 may flow through antipads 160, 162, 164, and 166. These leakage currents may cause noise on trace or stipline 106. In an example, leakage currents 190 may flow from an antipad away from a corresponding power via. For example, a leakage current 190 may flow along ground layer 116 from antipad 160 in a direction that is away from power via 140 and towards ground region 102. Another leakage current 190 may flow along portion 130 of ground layer 116 from antipad 160 in a direction that is away from power via 140 and towards power via 142. A leakage current 190 may flow along portion 130 of ground layer 116 from antipad 162 in a direction that is away from power via 142 and towards power via 140. In an example, the two leakage currents 190 along portion 130 may be in opposite directions such that the noise coupling on trace or stipline 106 from these two leakage currents may be greatly reduced as compared to a situation with only one leakage current flowing in a particular direction.

Another leakage current 190 may flow along portion 132 of ground layer 116 from antipad 162 in a direction that is away from power via 142 and towards power via 144. A leakage current 190 may flow along portion 132 of ground layer 116 from antipad 164 in a direction that is away from power via 144 and towards power via 142. In this example, the two leakage currents 190 along portion 132 may be in opposite directions such that the noise coupling on trace or stipline 106 from these two leakage currents may be greatly reduced as compared to a situation with only one leakage current flowing in a particular direction.

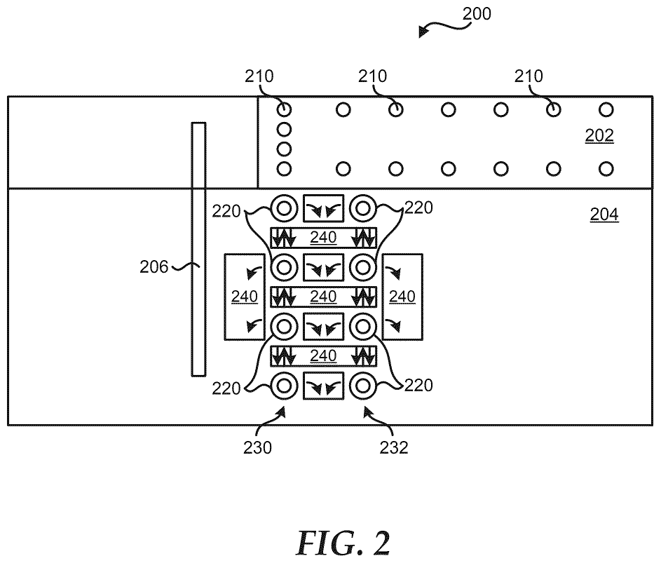

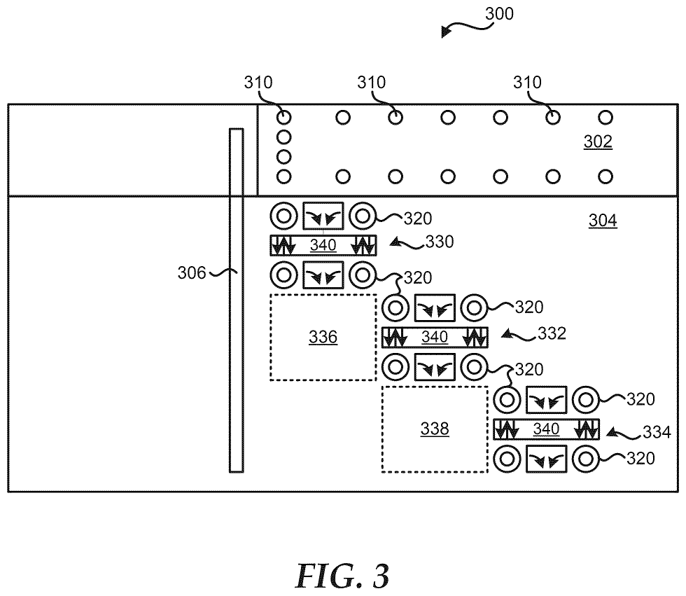

Another leakage current 190 may flow along portion 134 of ground layer 116 from antipad 164 in a direction that is away from power via 144 and towards power via 146. A leakage current 190 may flow along portion 134 from antipad 166 in a direction that is away from power via 146 and towards power via 144. In this example, the two leakage currents 190 along portion 134 may be in opposite directions such that the noise coupling on trace or stipline 106 from these two leakage currents may be greatly reduced as compared to a situation with only one leakage current flowing in a particular direction. Another leakage current 190 may flow along portion 136 in a direction that is away from power via 146. While portions 130, 132, 134, and 136 are illustrated as only being located in between corresponding power vias 140, 142, 144, and 146, ground layer 116 may include other portions that extend in all directions from antipads 160, 162, 164, and 166. Thus, leakage currents 190 may flow in the direction 180 of conduction current in all of the portions of ground layer 116 as shown in FIGS. 2 and 3.

In certain examples, leakage currents 190 flowing in different directions from the multiple non-shared antipads 150, 152, 154, 156, 160, 162, 164, and 166 may be smaller as compared to leakage currents from shared antipads. Thus, non-shared antipads 150, 152, 154, 156, 160, 162, 164, and 166 may reduce leakage currents 190, which in turn may reduce noise coupling between the leakage currents and signal on trace or stripline 106.

FIG. 2 illustrates the top of a portion of a printed circuit board 200 for an information handling system according to at least one embodiment of the present disclosure. In an example, printed circuit board 200 may be substantially similar to printed circuit board 100 of FIG. 1. Printed circuit board 200 includes a ground region 202, a VRM region 204, and a signal trace or stripline 206. Ground region 202 includes multiple ground vias 210 and different ground layers physically and electrically coupled to the ground vias. VRM region 204 includes multiple power vias 220. Signal trace or stripline 206 is located within printed circuit board 200 and extend adjacent to, but does not intersection with, ground vias 210 and power vias 220. Printed circuit board 200 may include additional components without varying from the scope of this disclosure.

In certain examples, power vias 220 may be positioned or arranged in multiple columns, such a column 230 and column 232. In an example, each power via 220 may have a corresponding non-shared antipad within a ground layer, such that different portions 240 of the ground layer are created around the power vias. Columns 230 and 232 may create a sequence of non-shared antipads around corresponding power vias 220. This sequence of antipads may create or enable leakage currents to travel or flow through the ground layer that the antipads are located within.

During operation of VRM 204, a conduction current is created within the VRM, which as described above may create multiple areas of leakage currents through the antipads and along portions 240 of the ground layer. As illustrated, the leakage currents that travel along portions 240 in between two adjacent power vias 220 may be in opposite directions. These leakage currents may reduce noise coupling with a signal propagated along trace or stripline 206. Additionally, the leakage currents on portions 240 of the ground layer from the non-shared antipads of power vias 220 may be smaller as compared to leakage currents from shared antipads, which in turn may reduce noise coupling with a signal propagated along trace or stripline 206.

FIG. 3 illustrates a portion of a printed circuit board 300 according to at least one embodiment of the present disclosure. In an example, printed circuit board 300 may be substantially similar to printed circuit board 100 of FIG. 1. Printed circuit board 300 includes a ground region 302, a VRM region 304, and a signal trace or stripline 306. Ground region 302 includes multiple ground vias 310 and different ground layers physically and electrically coupled to the ground vias. VRM region 304 includes multiple power vias 320. Signal trace or stripline 306 is located within printed circuit board 300 and extend adjacent to, but does not intersection with, ground vias 310 and power vias 320. Printed circuit board 300 may include additional components without varying from the scope of this disclosure.

In certain examples, power vias 320 may be positioned or arranged in multiple groups or structures, such power via groups 330, 332, and 334. A ground layer within printed circuit board 300 may include low or weak current regions 336 and 338 as will be described herein. In an example, each power via 320 may have a corresponding non-shared antipad within a ground layer, such that different portions 340 of the ground layer are created around the power vias. Based on each power via having a corresponding non-shared antipad, groups 330, 332, and 334 may be referred to as non-shared antipad groups. As illustrated, non-shared antipad groups 330, 332, and 334 may be staggered such that no group overlaps with any other group within the ground layer of printed circuit board 300. This sequence or patterned antipad groups may create or enable small amounts of leakage current to travel or flow through the ground layer that the antipads are located within.

During operation of VRM 304, a conduction current is created within the VRM, which as described above may create multiple areas of leakage currents through the antipads and along portions 340 of the ground layer. As illustrated, the leakage currents that travel along portions 340 in between two adjacent power vias 320 may be in opposite directions. These leakage currents may reduce noise coupling with a signal propagated along trace or stripline 306. Additionally, the leakage currents on portions 340 of the ground layer from the non-shared antipads of power vias 320 may be smaller as compared to leakage currents from shared antipads, which in turn may reduce noise coupling with a signal propagated along trace or stripline 306.

In an example, low or weak current regions 336 and 338 may have a limited amount of leakage current based on these regions not including any antipads. For example, weak current region 336 is outside of non-shared antipad groups 330 and 332 and as a result this region does not include any antipads. Without antipads in weak current region 336, the region does not include any area where portions of the conduction current of VRM region 304 may leak into the ground layer. Based on reduce amount of leakage currents within regions 336 and 338, these regions may have the lowest levels of noise coupling with a signal propagated on trace or stripline 306 as compared to other portions of VRM region 304.

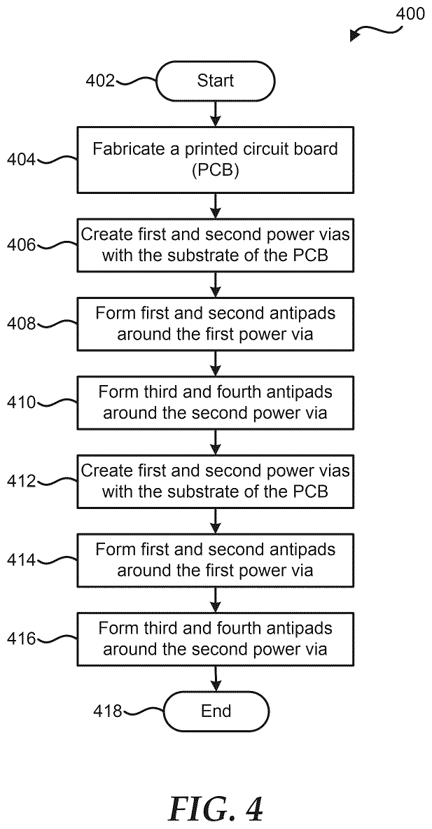

FIG. 4 shows a method 400 for fabricating a printed circuit board with power vias having non-shared antipads according to at least one embodiment of the present disclosure, starting at block 402. Not every method step set forth in this flow diagram is always necessary, and certain steps of the methods may be combined, performed simultaneously, in a different order, or perhaps omitted, without varying from the scope of the disclosure.

At block 404, a printed circuit board is fabricated. In an example, the fabricated circuit board includes a trace along a layer of a substrate of the printed circuit board. At block 406, first and second power vias are created within the substrate. The first and second power vias may be located adjacent to the trace. At block 408, first and second antipads are formed around the first power via. In an example, the first antipad is located within the first ground layer of the substrate and the second antipad is located within the second ground layer of the substrate.

At block 410, third and fourth antipads are formed around the second power via. In an example, the third antipad is located within the first ground layer and the fourth antipad is located the second ground layer of the substrate. In certain examples, the first and third antipads are non-shared antipads between the first and second power vias, wherein the second and fourth antipads are non-shared antipads between the first and second power vias. In an example, a portion of the first ground layer is located in between the first and third antipads, and a portion of the second ground layer is located in between the second and fourth antipads. The length of the portions may be greater than a threshold length, such as 5 mils.

At block 412, third and fourth power vias are formed within the substrate. At block 414, fifth and sixth antipads are formed around the third power via. The fifth antipad is located within the first ground layer and the sixth antipad is located within the second ground layer. At block 416, seventh and eighth antipads are formed around the fourth power via and the flow ends at block 418. In an example, the seventh antipad is located within the first ground layer and the eighth antipad is located the second ground layer of the substrate. The fifth and seventh antipads are non-shared antipads between the third and fourth power vias, and the sixth and eighth antipads are non-shared antipads between the third and fourth power vias.

In certain examples, the first, second, third and fourth antipads may form a first group of antipads, and the fifth, sixth, seventh and eighth antipads form a second group of antipads. In an example, the first group of antipads are staggered from the second group of antipads. In certain examples, the power vias may form a part of a voltage regulator module in the printed circuit board.

FIG. 5 shows a generalized embodiment of an information handling system 500 according to an embodiment of the present disclosure. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 4394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off of a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A printed circuit board comprising:
a substrate;
a trace routed along a layer within the substrate;
a ground layer within the substrate;
a plurality of power vias including first and second power vias, wherein the power vias are adjacent to the trace within the substrate;
a first antipad around the first power via, wherein the first antipad is located within the ground layer of the substrate; and
a second antipad around the second power via, wherein the second antipad is located within the ground layer, wherein the first and second antipads are non-shared antipads between the first and second power vias.

2. The printed circuit board of claim 1, wherein a portion of the ground layer is located in between the first and third antipads.

3. The printed circuit board of claim 2, wherein a length of the portion is greater than a threshold length.

4. The printed circuit board of claim 3, wherein the threshold length is 5 mils.

5. The printed circuit board of claim 1, wherein a first leakage current from the first power via cancels a second leakage current from the second power via.

6. The printed circuit board of claim 1, further comprising:
third and fourth power vias;
a third antipad around the third power via, wherein the third antipad is located within the ground layer; and
a fourth antipad around the fourth power via, wherein the fourth antipad is located within the ground layer, wherein the third and fourth antipads are non-shared antipads between the third and fourth power vias.

7. The printed circuit board of claim 6, wherein a first group of non-shared antipads including the first antipad is staggered from a second group of antipads including the second antipad.

8. The printed circuit board of claim 1, wherein the power vias are part of a voltage regulator module in the printed circuit board.

9. A method comprising:
fabricating a printed circuit board, wherein the printed circuit board includes a trace along a layer of a substrate of the printed circuit board;
creating first and second power vias within the substrate, wherein the first and second power vias are adjacent to the trace;
forming first and second antipads around the first power via, wherein the first antipad is located within a first ground layer of the substrate and the second antipad is located within a second ground layer of the substrate; and
forming third and fourth antipads around the second power via, wherein the third antipad is located within the first ground layer and the fourth antipad is located the second ground layer of the substrate, wherein the first and third antipads are non-shared antipads between the first and second power vias, wherein the second and fourth antipads are non-shared antipads between the first and second power vias.

10. The method of claim 9, wherein a portion of the first ground layer is located in between the first and third antipads.

11. The method of claim 10, wherein a length of the portion is greater than a threshold length.

12. The method of claim 11, wherein the threshold length is 5 mils.

13. The method of claim 9, wherein a portion of the second ground layer is located in between the second and fourth antipads.

14. The method of claim 9, further comprising:
forming third and fourth power vias within the substrate;
forming fifth and sixth antipads around the third power via, wherein the fifth antipad is located within the first ground layer and the sixth antipad is located within the second ground layer; and
forming seventh and eighth antipads around the fourth power via, wherein the seventh antipad is located within the first ground layer and the eighth antipad is located the second ground layer of the substrate, wherein the fifth and seventh antipads are non-shared antipads between the third and fourth power vias, wherein the sixth and eighth antipads are non-shared antipads between the third and fourth power vias.

15. The method of claim 14, wherein a first group of the first, second, third and fourth antipads are staggered from a second group of the fifth, sixth, seventh and eighth antipads.

16. The method of claim 9, wherein the first and second power vias are part of a voltage regulator module in the printed circuit board.

17. A printed circuit board comprising:
a substrate;
a trace routed along a layer within the substrate;
first and second ground layers within the substrate;
first and second power vias disposed adjacent to the trace within the substrate;
first and second antipads around the first power via, wherein the first antipad is located within the first ground layer of the substrate and the second antipad is located within the second ground layer of the substrate; and
third and fourth antipads around the second power via, wherein the third antipad is located within the first ground layer and the fourth antipad is located the second ground layer of the substrate, wherein the first and third antipads are non-shared antipads between the first and second power vias, wherein the second and fourth antipads are non-shared antipads between the first and second power vias, wherein a portion of the first ground layer is located in between the first and third antipads, wherein a portion of the second ground layer is located in between the second and fourth antipads.

18. The printed circuit board of claim 17, further comprising:
third and fourth power vias;
fifth and sixth antipads around the third power via, wherein the fifth antipad is located within the first ground layer and the sixth antipad is located within the second ground layer; and
seventh and eighth antipads around the fourth power via, wherein the seventh antipad is located within the first ground layer and the eighth antipad is located the second ground layer of the substrate, wherein the fifth and seventh antipads are non-shared antipads between the third and fourth power vias, wherein the sixth and eighth antipads are non-shared antipads between the third and fourth power vias.

19. The printed circuit board of claim 18, wherein a first group of the first, second, third and fourth antipads are staggered from a second group of the fifth, sixth, seventh and eighth antipads.

20. The printed circuit board of claim 17, wherein a length of the portion is greater than a threshold length.
